(19) United States
(12) Patent Application Publication
(10) Pub. No.: US 2005/0196686 A1
(43) Pub. Date: Sep. 8, 2005

(54) Method for compensation of the shortening of line ends during the formation of lines on a wafer

(76) Inventors: Dirk Meyer, Essex (GB); Thomas Henkel, Dresden (DE); Jorg Thiele, Munchen (DE); Martin Keck, Munchen (DE)

Correspondence Address: SLATER & MATSIL LLP, 17950 PRESTON ROAD, SUITE 1000, DALLAS, TX, 75252, US

(21) Appl. No.: 11/066,734

(22) Filed: Feb. 25, 2005

(30) Foreign Application Priority Data
Feb. 25, 2004 (DE) 10 2004 009 173.0

(51) Int. Cl. G03F 9/00; G03F 7/20

(52) U.S. Cl. 430/5; 430/30; 430/322

(57) ABSTRACT

In order to compensate for the shortening of line ends (30) in a circuit design of an integrated circuit, in a first step, hammerheads or serifs (50) are attached to the line ends (30) by means of rule-based OPC corrections. The line ends modified in this way are revised further by downstream application of a simulation-based OPC correction before mask or direct wafer writer data are calculated. As a result of the formation of the pattern revised by the simulation-based correction on the wafer, there actually arises in an approximate manner owing to the proximity effects the layout created by the rule-based correction with the supplemented line ends (30) on the wafer.

This application claims priority to German Patent Application 102004009173.0, which was filed Feb. 25, 2004, and is incorporated herein by reference.

### TECHNICAL FIELD

The invention relates to a method for compensation of a shortening of line ends on a wafer, and also relates to a method for correction of proximity effects (OPC) in circuit designs of integrated circuits.

### BACKGROUND

In order to fabricate integrated circuits, first of all circuit designs are created. The terms circuit design and circuit layout are used synonymously hereinafter for electronically stored plans in which forms, orientation and/or positions are assigned to structure elements to be formed. In this case, it is also possible, the other way round, to assign a value to each position within the plan, for example a “0” for exposure and a “1” for non-exposure.

The designs are decomposed plane by plane and the resulting patterns of the circuit planes are drawn on photomasks by means of mask writing devices. In lithographic projection steps, the patterns are progressively transferred from the photomasks to a semiconductor wafer resist-coated with a photosensitive layer. After each projection step, a number of postprocessing steps are carried out, for example etching, implantation, planarization or deposition processes etc.

As an alternative, provision may also be made for drawing the decomposed designs, after conversion into writer formats, directly onto the wafer by means of so-called direct e-beam writing. Corresponding exposure apparatus for wafers are referred to hereinafter as direct wafer writers.

In the case of high integration densities or particularly small feature sizes, for example in the region of the resolution limit of the projection system, imaging errors often occur on the wafer. If the structure elements lie particularly close together, then it is also possible, in particular, for undesirable and unavoidable light contributions of respectively adjacent structure elements to occur in the photosensitive layer. These proximity effects, also called proximity errors, may be caused by lens imperfections, varying resist thicknesses, microloading effects, light scattering or diffraction at chromium or other absorber edges on the mask, etc. The person skilled in the art of lithographic projection will also take account of further causes of the arising of proximity errors.

Besides improving the respective process conditions, compensation of the effects by taking into consideration a positive or negative bias as early as in the circuit designs is employed for avoiding these proximity errors. This is possible particularly when the proximity errors occur systematically. Such compensation or correction of the proximity errors or proximity effects is also called optical proximity correction (OPC). Thus, by way of example, outer corners of bending lines that are provided in the circuit designs are provided with additional serifs or the inner corners lying on the opposite side are provided with cutouts in order to avoid so-called corner rounding during the imaging projection on the wafer. The basic principle is that structures that are reduced in size on account of the projection are represented in enlarged fashion for compensation purposes in the circuit design, and vice versa.

A related problem is so-called line end shortening, a shortening of the line ends within circuit planes. The ends of lines in a plane typically extend as far as a position where they are contact-connected from a next circuit plane. Overlay and alignment tolerances are in this case reckoned in the positioning.

It is precisely in circuits with very fine feature sizes for lines that the proximity errors have a considerable effect on the shortenings of the lines. Therefore, if a bias were not taken into account in the circuit design in the context of an OPC correction, which compensates again for the line end shortening, then it might happen that the contact connection originating from the next circuit plane is not connected to the line end.

Such biases are not left to a downstream OPC method, rather rules by which, for example, line ends must project beyond the point of impingement of a contact connection are already stored in the design. This rule is referred to hereinafter as “minimum length of the overlap region.”

In order to create a layout, the rules are determined with the aid of experimental measurements. In the case of the line ends, by way of example, wafers with a multiplicity of lines of different widths are exposed and the line end shortenings thereof are measured. In addition to the budget for line end shortening, the design rule “minimum length of the overlap region” also additionally includes a budget for alignment or positional accuracy errors for the mutual orientation of two patterned layer planes.

Overall, a comparatively large amount of space is therefore lost in the circuit layout of the relevant circuit plane, which has a particularly disadvantageous effect precisely in highly integrated layouts. The distance between the contact position and the further lines adjacent to the line end therefore has to be chosen to be correspondingly large.

### SUMMARY OF THE INVENTION

In one aspect, the present invention proposes a method by which the effect of line end shortening can be compensated for more effectively. For example, one embodiment enables an increase in the structure density on a wafer for a predetermined technology generation, i.e., minimum feature size.

In one embodiment, a method for compensation of a shortening of line ends occurring during the formation of lines on a wafer, includes creating a circuit design in which a multiplicity of lines with at least one line end are designed. A rule-based correction of proximity effects for insertion or supplementation of one or more serifs, for example of hammerheads, is carried out in the circuit design onto the line end. A simulation-based correction of proximity effects at the line end including the serifs in the circuit design is carried out, so that in the case of an actual formation of the line end on the wafer, the line end arises on the wafer in a form that includes the supplementation by the serifs. The circuit design that has been revised by simulation-based correction is imaged as a pattern with the line end supplemented by the serifs on the wafer.

A rule-based OPC correction step is combined with a simulation-based OPC correction step. On the basis of the rule-based OPC correction, a first intermediate design of the circuit plane is produced, which is revised by the simulation-based OPC correction. A particular effect occurs by virtue of the fact that the rule-based OPC correction already performs the insertions or attachments, necessary for compensating for proximity errors, to the line ends for the purpose of preventing line end shortening and thus establishes them in the circuit design. When used as input information for the simulation-based OPC correction step, the modified line ends of the circuit design are simulated as a result to be obtained on a wafer. As a result, the line ends are thereby overformed again, for example by additions or else by omissions at the line ends. On account of this, projection- and process-stable line ends are constrained by the two-stage OPC correction.

By virtue of the generally automated production or insertion and supplementation of one or more serifs, which preferably have the form of so-called hammerheads, the very complex and surroundings-dependent rules may be responsible for the design of line ends. In particular, it is now possible solely to take account of only the overlay tolerance budget of the lithographic projection process in the rule “minimum length for the overlap region.” The insertion of the serifs with subsequent overforming by means of the simulation-based OPC correction in this case compensates for the shortening of line ends and may even lead to an overcompensation of the line end shortening.

The methods of operation of rule- and simulation-based OPC corrections are explained below. Both types of OPC corrections are sufficiently known by themselves to the person skilled in the art of circuit design. Both types are based on making a prediction about the anticipated distortions on account of proximity errors.

In the case of rule-based OPC correction, measurements of line and/or gap widths are carried out and the results are in each case related to the geometrical arrangement of structures or structure elements in the vicinity of an edge of the line examined. The measurements may be physical measurements, but using simulation results for this as well is not ruled out. A fundamental factor, however, is that the results, i.e., edge displacements on account of the assumed or actual proximity errors, are stored in the tables whose row entries in each case reflect a geometrical configuration.

Such a row entry corresponds to one of the rules. Upon application of the rule-based OPC correction, structure edges of a circuit design or of a circuit plane of the circuit design are traced or scanned and the local geometrical configurations are determined and compared with the table entries. The rules stored for each table entry, for example minimum distance from an adjacent line that runs parallel having the width X, etc., are employed in order that when a rule is contravened, an addition or omission that is predefined for this case is carried out at the relevant position.

Simulation- or model-based OPC correction involves carrying out—if appropriate in iterative steps—simulations of the circuit patterns that are currently to be formed on a mask into the photosensitive layer on a wafer. The result that is obtained on the wafer and that may also involve properties of the resist being taken into account is compared with a reference pattern. The reference pattern generally corresponds to the original circuit design, but according to the invention corresponds to the layout that has already been modified by the rule-based OPC correction. The difference between the simulation result and the reference image in each case represents a measure of the displacement of structure edges in the circuit design of the preceding step. In this way, the simulation approximates to a circuit design which is such that it can obtain the original circuit design in a projection on the wafer.

In the case of sublithographic serifs or hammerheads, i.e. insertions having a length that is less than the resolution limit of the exposure apparatus used for the projection, it is not possible, of course, by application according to the invention of the simulation-based OPC correction, to obtain precisely the circuit design that has already been modified by the rule-based OPC correction as a result on the wafer. This would not necessarily be desirable either according to the invention; the intention, rather, is only to achieve stability of the imaging of line ends during projection.

The result of the simulation-based correction is a once again modified circuit design of the circuit plane. The method according to the invention provides for generating from this a control instruction file for a mask writing device that draws the corrected circuit design of the relevant circuit plane on a mask. On the basis of such a control instruction file, a mask manufacturer can manufacture the relevant mask and make it available to the manufacturer of the integrated circuits. The mask error that occurs during the fabrication of the pattern on the mask, in particular with respect to line end shortening, can be regarded as negligible in this case. The mask error may also already be included in the wafer measurement results if structures on the test mask suffer from line end shortening.

The manufacturer of the integrated circuits uses the mask provided to perform the lithographic projection step on a wafer coated with the photosensitive resist. The steps of mask and wafer exposure are sufficiently known to the person skilled in the art and constitute steps outside the method according to the invention. It is also conceivable, in principle, to employ the method according to the invention for the—currently only for low volumes—direct writing method for semiconductor wafers, primarily in the logic field.

### BRIEF DESCRIPTION OF THE DRAWINGS

The invention will now be explained in more detail on the basis of an exemplary embodiment with the aid of a drawing, in which:

FIG. 1 shows a flow diagram of the method according to the invention;

FIGS. 2a and 2b, collectively FIG. 2, show a schematic illustration of line ends with a comparison between the prior art (FIG. 2a) and the present invention (FIG. 2b);

FIG. 3 shows a diagram with a comparison between the line end shortenings obtained in accordance with the prior art (squares) and in accordance with the present invention (triangles) as a function of the depth of field; and

FIG. 4 shows an illustration of serifs that are additionally formed according to the invention at an exemplary line end in each case after individual steps of the method in comparison with the prior art.

The following list of reference symbols can be used in conjunction with the figures
14 contact connection
16′ rule “minimum distance of the overlap region” (invention)
16 rule “minimum distance of the overlap region” (prior art)
20 actual line end on the substrate in the case of positional accuracy error of zero, minor shortening
22 actual line end on the substrate in the case of a positional accuracy error of zero, major shortening
30 line end
40 tolerance budget for positional accuracy errors
42 tolerance budget for errors owing to line end shortening
50 serifs, hammerheads (according to the invention)
50′, 50″ serifs, hammerheads (according to the invention), after simulation-based OPC
51 serifs (prior art)
60 line end shortening (invention: slight)
61 line end shortening (prior art: considerable)
101 interaction of the generation of design and serif rules

### DETAILED DESCRIPTION OF ILLUSTRATIVE EMBODIMENTS

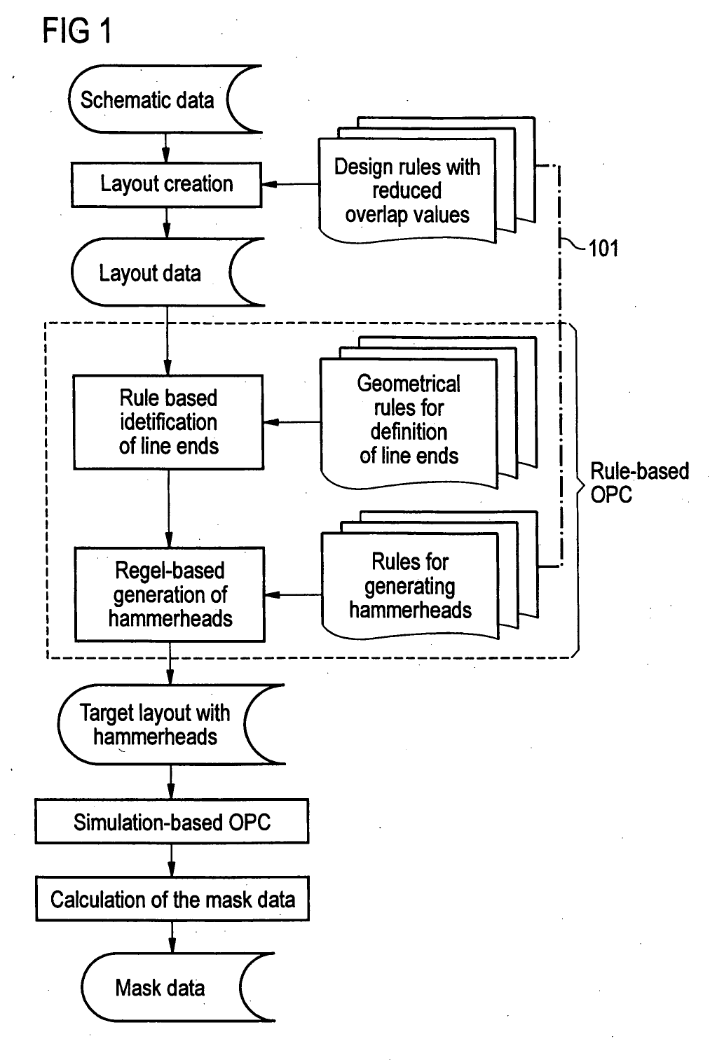

FIG. 1 shows an exemplary embodiment of the present invention on the basis of a flow diagram. So-called “schematic data” with the functional properties of the integrated circuit to be fabricated are initially present. A full-custom design, i.e., a circuit design, is created therefrom (step: layout creation). As an alternative, the design may also involve a standard cell in a semi-custom flow.

Design rules are made available for carrying out this step of layout creation, the design rules also including the design rule “minimum length for the overlap region.” The layout creation is carried out manually by a designer for example with the aid of suitable software tools that enable a limited degree of automation. This applies primarily to high-volume products such as memory chips, for example, for low-volume products, particularly in ASIC fabrication, the functional conditions of the schematic data can be converted into layout data, i.e., the circuit design, in a fully automatic manner on the basis of higher programming languages.

In all of the intermediate steps, a so-called design rule checker (DRC) may repeatedly be applied to the circuit design. The DRC marks contraventions of the design rule and enables the circuit design to be revised. By way of example, if the distances between the line end edges 10, 10′ and the edges 12, 12′ of a contact connection 14 stemming from another circuit plane are chosen to be too small, then the relevant position is marked by the design rule check, so that the designer is able or has to correspondingly adapt the distance.

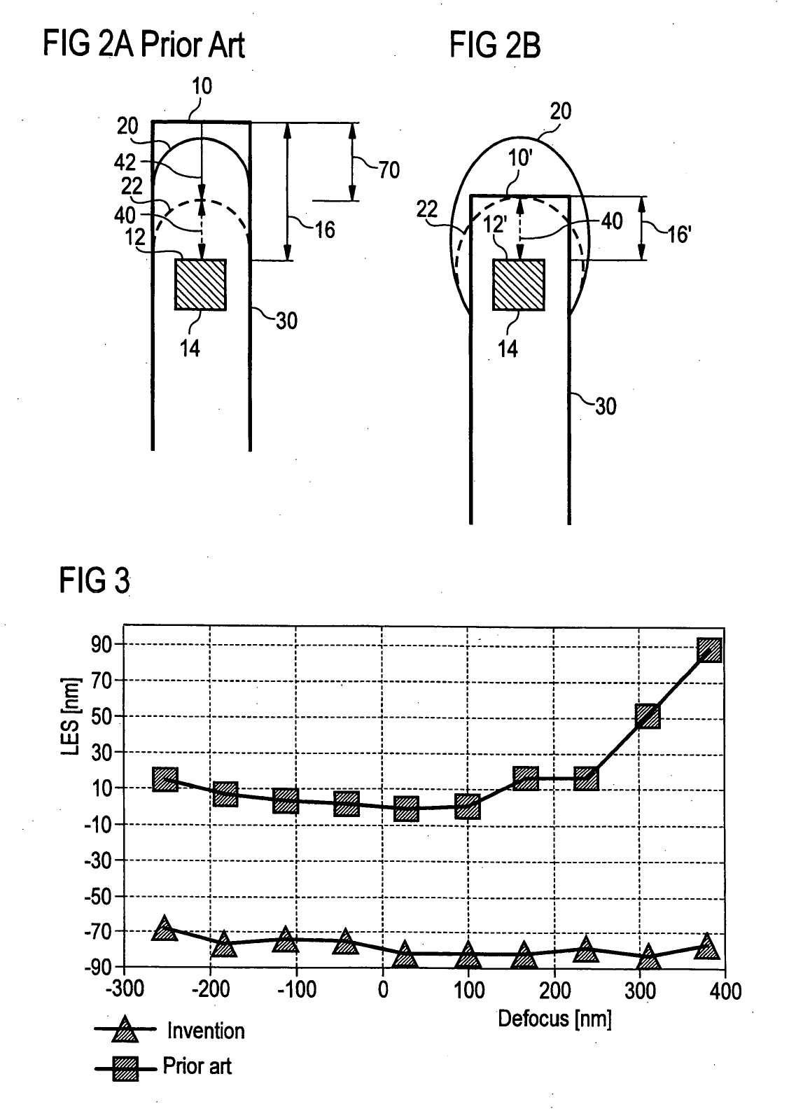

This distance will generally be chosen to be as small as possible in order to save space. It is therefore adapted in accordance with the design rule 16, 16′ “minimum length for the overlap region” as can be seen in FIG. 2.

Returning to FIG. 1, the next step to take place is the rule-based identification of line ends. It suffices according to embodiments of the invention also possibly to correct only one line with a line end in a targeted manner. Preferably, however, all line ends, but at least those in highly integrated pattern regions, are corrected. The actual selection of the line ends to be corrected is controlled by the provision of geometrical rules.

The geometrical rules define whether or not a structure is a line end. By way of example, items of information are stored here that define the limit from which a terminating structure is to be regarded as a pad or a lug that simply only projects from an area is merely to be regarded as a bulge. Items of geometrical information that are included in the line identification are also, for example, the length of further adjoining segments and also the relative position thereof with respect to the line end segment considered.

If the relevant line ends have been identified on the basis of these geometrical rules, then the correction can be calculated. Rules for generating so-called hammerheads are prescribed for this purpose. As already described, the rules are calculated on the basis of experimental or here simulative measurements of predefined hammerheads in a wide variety of configurations of surroundings and are stored. Depending on the currently identified line end configuration and the surroundings thereof, the suitable rules, i.e., hammerheads, are read out and inserted into the circuit design. During the simulation for generating hammerheads for edge regions of the process window for the lithographic projection, it is ensured that the line ends cannot be short-circuited with adjacent lines.

At the same time, however, it is ensured that enough space for the generation of the hammerheads is kept free in the design rules for minimum distances between line ends and adjacent structures. The design rules for the reduced overlap values of the minimum length rules and also rules for generating hammerheads are accordingly coordinated with one another. The coordination 101 is carried out in the front end of performing the method according to the invention.

The result of such a rule-based OPC reduced to the correction of line ends is a modified circuit design, also called target layout in the figure, which now has serifs or hammerheads in the region of the line ends. This target layout serves as an input data set for a now subsequent simulation-based OPC. This means that modifications or edge displacements are carried out in the circuit design until, to the furthest possible approximation, the target layout is obtained as a result on the wafer in a simulation or else another criterion for terminating the iteration is attained. Since the line ends have already been widened by the rule-based OPC, a significantly widened result is achieved in the final circuit design as a result of the simulation-based OPC in comparison with the prior art, where only one of the two methods is carried out.

The result can be seen in FIG. 2. FIG. 2a shows a line end in accordance with the prior art. In the most favorable case, the line 30 of the circuit design is shortened to form a line 20 in the case of an actual projection. A typical line end shortening, by contrast, leads to a line 22 on the wafer (dashed line) whose edge distance from the contact connection 14 of a next circuit plane only corresponds to the overlay budget 40 of the lithographic projection. The difference between this distance and the distance between the outermost line edge 10 and the contact connection 12 corresponds to the budget for the line end shortening 42. The sum of the budget 42 and the budget 40 corresponds to the design rule “minimum length of the overlap region” 16.

FIG. 2b schematically shows a line end when the method according to the invention is carried out. In the case of line end shortenings that occur only to a slight extent, the line 20 actually formed on the wafer is even lengthened compared with that line 30 from the circuit design. In the case of a proximity error that occurs to a maximum extent, the length of the line 22 remains just constant (dashed line). The design rule 16′ with a reduced minimum length for the overlap region is just dimensioned in such a way that only the overlay budget 40 has to be complied with in the event of maximum line end shortening. The line 30 can thus be provided in shortened fashion from the outset in the layout. A space saving by the length 70, as illustrated in FIG. 2a, can thus be obtained.

On isolated lines it is possible to set an overcompensation by means of rules for generating the serifs or hammerheads that are adapted according to the invention. The overcompensation is nominally superfluous but, when viewed statistically, inserts a yield margin since defects are less critical for such situations.

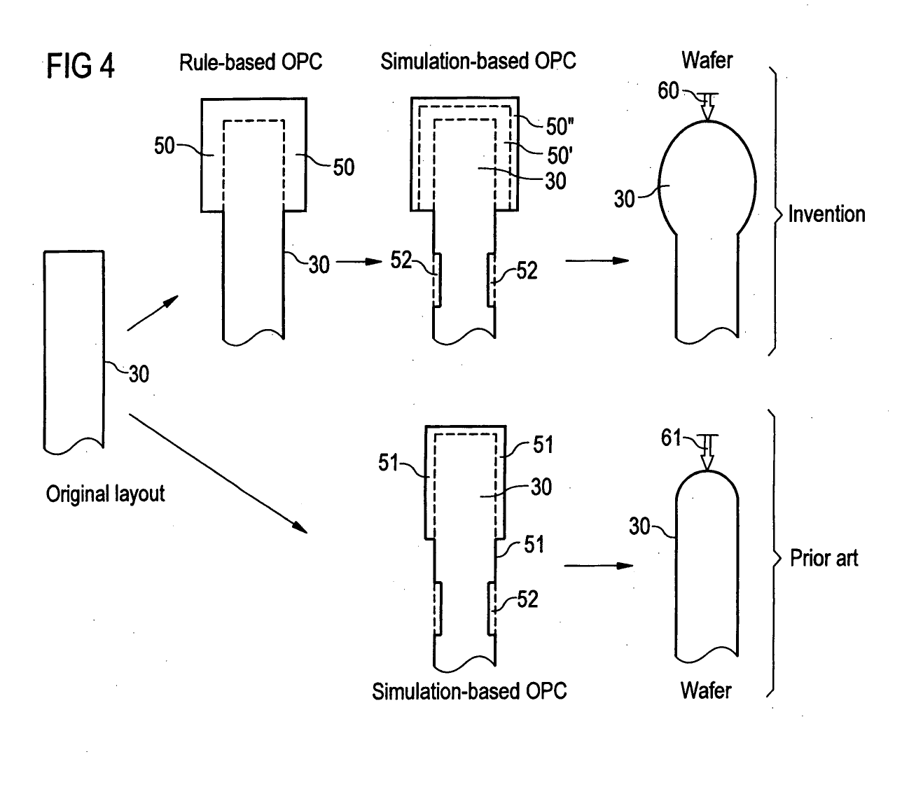

FIG. 4 shows a detail from a circuit design with a line end 30 on the left-hand side. The sequence of line end overformings that arises upon application of the method according to the invention is illustrated in the upper part of the figure. A sequence in accordance with the prior art is shown in the lower half of the figure for comparison. Proceeding from the unprocessed and original line end 30 represented on the left-hand side, solely a simulation-based OPC method is carried out in the prior art (FIG. 4, at the bottom in the middle). This results in serifs or omission 52, which are added with the proviso that, taking account of the imaging properties or errors during the lithographic projection or during direct writing on the mask or wafer, the line end illustrated on the left-hand side is produced again as dimensionally accurately as possible on the wafer. The result can be seen at the bottom on the right in FIG. 4. The original width of the line can be retained well as a result, but a considerable shortening 61 of the line end cannot be prevented.

Proceeding from the original line end 30 on the left-hand side of FIG. 4, the next illustration in the sequence according to the invention shows the addition of serifs 50. The addition is realized by means of rule-based OPC correction with the generation of hammerheads.

The next step (FIG. 4, at the top in the middle on the right) applies the known simulation-based method to the now already precorrected line end 30. The serifs 50 are reworked to form serifs 50′. In this example, further narrow serifs 50″ are attached to the serifs 50 in this case. They serve to enable the detail shown at the top in the middle on the left in FIG. 4 to be imaged as dimensionally accurately as possible.

The result on the wafer can be seen at the top on the right in FIG. 4. The widening of the line end 30 to form a head is clearly discernable, which has the effect that the line end shortening 60 turns out to be significantly smaller here than in the case of the prior art (cf. FIG. 4 at the bottom on the right).

FIG. 3 shows a comparison of measurement results of the line end shortenings between the two-stage method according to the invention (triangle symbols) and a method in accordance with the prior art (square symbols). The diagram illustrates the line end shortening (LES) in nanometers, plotted against the defocus.

The diagram shows the improved stability of the line end shortening at different focus settings. It is possible to adapt the rule for generating hammerheads in such a way that the line end shortening, as shown by the dashed line in FIG. 2b, on average precisely just disappears.

Other manufacturing fluctuations can also be examined in the same way as in the example shown in FIG. 3. The rules can thus be adapted correspondingly on the basis of the results, e.g., with regard to dose fluctuations, etch bias variations, etc.

One effect of the invention is based in this respect on the previously existing trend toward line end shortening on one side, for a given variation or uncertainty, being compensated for by a further bias in such a way that only the variation of the line shortening itself and no longer the absolute value is applicable in the result. The bias is even chosen to be so large that if need be an overcompensation, that is to say a line end lengthening is caused. Short circuits that possibly occur are prevented by means of the determination and simulation of the rules for generating the hammerheads.

1. A method for forming lines on a wafer, the method comprising:
creating a circuit design in which a multiplicity of lines with at least one line end are designed;
carrying out a rule-based correction of proximity effects for insertion or supplementation of one or more serifs in the circuit design onto the line end;
carrying out a simulation-based correction of proximity effects at the line end including the serifs in the circuit design, so that in the case of an actual formation of the line end on the wafer, said line end arises on the wafer in a form that includes the supplementation by the serifs;
imaging the circuit design that has been revised by simulation-based correction to form a pattern with the line end supplemented by the serifs on the wafer.

2. The method as claimed in claim 1, wherein the step of carrying out the rule-based correction comprises:
providing geometrical rules for identifying line ends; and
performing a rule-based identification of the at least one line end on the basis of the geometrical rules.

3. The method as claimed in claim 1, wherein the formation of the pattern on the wafer comprises:
forming a control instruction for a mask writer from the circuit design;
forming the pattern on a mask from the control instruction in the mask writer; and
transferring the pattern from the mask to the wafer in a lithographic projection step.

4. The method as claimed in claim 1, wherein the formation of the pattern on the wafer comprises:
forming a control instruction for a direct wafer writer from the circuit design; and
forming the pattern on the wafer from the control instruction in the direct wafer writer.

5. The method as claimed in claim 1, wherein rules for the production of serifs are prescribed for carrying out the step of inserting and supplementing serifs in the region of the identified line end.

6. The method as claimed in claim 5, wherein the rules for the production of serifs are obtained from simulations that are carried out for a multiplicity of geometrical configurations in a vicinity of a line end.

7. The method as claimed in claim 6, wherein the rules take account of distances between adjacent lines and the line end, and are stored in a library.

8. The method as claimed in claim 5, wherein the rules for the production of the at least one serif are determined experimentally.

9. The method as claimed in claim 1, wherein the rule-based correction is carried out by providing design rules that prescribe a minimum distance between a contact connection, which connects a line of the circuit plane to such a line of a second circuit plane, and the line end, the minimum distance exclusively representing a predetermined value of a relative positional accuracy.

10. The method as claimed in claim 1, wherein the at least one serif has a side with a length along which it is attached to the line end that amounts to more than the resolution limit of an exposure device provided for an actual exposure of the wafer.

11. The method as claimed in claim 1, wherein the serifs have a side with a length along which they are attached to the line end which amounts to less than the resolution limit of an exposure device provided for an actual exposure of the wafer.

12. The method as claimed in claim 1, wherein the serifs comprise hammerheads.

13. A system for compensation of a shortening of line ends on a wafer comprising:
a first computation module for carrying out a rule-based correction of proximity effects at a circuit design provided;
a rule library for producing at least one serif, which is connected to the first computation module;
a second computation module for carrying out a simulation-based correction of proximity effects at the circuit design that has been processed by the first computation module; and
a third computation module for calculating control data for a mask or direct wafer writer from the circuit design that has been processed by the second computation module.

14. A method of making a photomask, the method comprising:
creating a circuit design that includes a plurality of lines, each line including at least one line end;
carrying out a rule-based correction of proximity effects for insertion or supplementation of one or more serifs in the circuit design onto the line end;
carrying out a simulation-based correction of proximity effects at the end line including the serif to supplement the serif; and
forming a pattern on a photomask substrate, the pattern being based upon the rule-based and simulation-based correction of proximity effects.

15. The method claimed in claim 14, wherein forming a pattern comprises deriving control instructions for a mask writer.

16. The method as claimed in claim 14, wherein the step of carrying out the rule-based correction comprises:
providing geometrical rules for identifying line ends; and
performing a rule-based identification of the at least one line end on the basis of the geometrical rules.

17. The method as claimed in claim 14, wherein rules for the production of serifs are prescribed for carrying out the step of inserting and supplementing serifs in the region of the identified line end.

18. The method as claimed in claim 17, wherein the rules for the production of serifs are obtained from simulations that are carried out for a multiplicity of geometrical configurations in a vicinity of a line end.

19. The method as claimed in claim 17, wherein the rules for the production of the at least one serif are determined experimentally.

20. The method as claimed in claim 14, wherein the rule-based correction is carried out by providing design rules that prescribe a minimum distance between a contact connection, which connects a line of the circuit plane to such a line of a second circuit plane, and the line end, the minimum distance exclusively representing a predetermined value of a relative positional accuracy.
